(19) United States
(12) Patent Application Publication
(10) Pub. No.: US 2022/0406691 A1
(43) Pub. Date: Dec. 22, 2022

(54) INTELLIGENT POWER MODULE

(71) Applicant: Richtek Technology Corporation, Zhubei City (TW)

(72) Inventors: Lung-Sheng Lin, Taichung (TW); Chih-Feng Huang, Hsinchu (TW)

(21) Appl. No.: 17/561,968

(22) Filed: Dec. 26, 2021

(30) Foreign Application Priority Data
Jun. 21, 2021 (TW) 110122620

(51) Int. Cl. H01L 23/495; H01L 23/31

(52) U.S. Cl. CPC H01L 23/49527; H01L 23/3107; H01L 23/4952; H01L 23/49575

(57) ABSTRACT

An intelligent power module, which includes: a lead frame; a plurality of signal processing chips, disposed on the lead frame; at least one bridge die, configured to operably transmit signals among the signal processing chips; and a package structure, encapsulating the lead frame, the signal processing chips and the bridge die.

### CROSS REFERENCE

The present invention claims priority to TW 110122620 filed on Jun. 21, 2021.

### BACKGROUND OF THE INVENTION

### Field of Invention

The present invention relates to an intelligent power module, in particular to an intelligent power module including a bridge die for transmitting signals between or among processing chips.

### Description of Related Art

In the prior art, the intelligent power module needs to manage complex signal connection lines. For example, as shown in FIG. 1, the driver chip 110 and the power chips 115 in the intelligent power module 10 need to be connected to the lead frame 120 and other chips for transferring signals in between, wherein the encapsulating structure 130 takes a large space to accommodate these components. The capability of the prior art intelligent power module 10 is limited by the layout of the lead frame 120; it cannot afford complex signal connections (it only allows, for example, one driver chip 110 having signal connections with two power chips 115).

The prior art intelligent power module 20 in FIG. 2 includes a printed circuit board (PCB 210) with a micro-processor unit (MCU) 220 on it. The MCU 220 needs many signal connections with the PCB 210 for various signal communications of different options, so the complexity of the connection layout is even more than the intelligent power module 10 in FIG. 1. The intelligent power module 20 needs to provide space for accommodating the PCB 210, and space for accommodating a fixing bracket 215 for mounting the PCB 210, so the encapsulating structure 240 of the intelligent power module 20 becomes very large in size. Besides, there are many bonding wires W distributed on the PCB 210, which also require the intelligent power module 20 to provide space in addition to the PCB 210 and the fixing bracket 215, and the bonding wires W need to be connected to different chips (for example, to the PCB 210, the power chip 230, etc.). Further, the manufacturing process for the PCB 210 is not a standard packaging process; the manufacturing process require various sub-processes and fixtures or equipment which may be provided by different manufacturers/vendors, increasing the complexity in manufacture and difficulty in quality control.

In view of the above, to overcome the drawbacks of the prior art intelligent power modules of large size, complex manufacturing process, and difficulty in quality control, the present invention provides a solution.

### SUMMARY OF THE INVENTION

In one perspective, the present invention provides an intelligent power module to address the aforementioned problems. The present invention has the following advantages over the prior art: reduced size, simple manufacturing process, centralized and easy wire bonding layout, and good control on the production quality. This intelligent power module includes: a lead frame; a plurality of signal processing chips, disposed on the lead frame; at least one bridge die, configured to operably transmit signals among the signal processing chips; and an encapsulating structure, encapsulating the lead frame, the signal processing chips, and the at least one bridge die.

The bridge die can provide multiple signal connection lines among the signal processing chips to centralize and simply the wiring layout. The circuit in the bridge die does not provide any calculation function; that is, it does not actively process signals. In some embodiments of the present invention, the intelligent power module includes the bridge die inside the encapsulating structure, but the intelligent power module does not include a PCB therein.

In one embodiment, the bridge die cooperates with multiple signal processing chips to transmit signals among the signal processing chips.

Because many signal connections among the chips are mostly collected within the bridge die, the bridge die greatly simplifies the layout of the bonding wires and reduces the overall size. In one embodiment, the driver chip in the present invention can be a single-phase gate drive integrated circuit; in another embodiment, the driver chip in the present invention can be a multi-phase gate drive integrated circuit for a higher signal operation capacity.

In one embodiment, a portion of the lead frame encapsulated by the encapsulating structure includes a plurality of bonding fingers. The bonding fingers are respectively connected to the signal processing chips, the bridge die, or the lead frame by bonding wires. In one embodiment, besides the wire bonding, the bridge die can also transmit signals among the signal processing chip via multiple through silicon vias (TSVs).

In one embodiment, a portion of the lead frame outside the encapsulating structure includes multiple leads for transmitting signals among the chips and an outside of the intelligent power module.

The objectives, technical details, features, and effects of the present invention will be better understood with regard to the detailed description of the embodiments below, with reference to the attached drawings.

### BRIEF DESCRIPTION OF THE DRAWINGS

FIGS. 1 and 2 show schematic diagrams of two intelligent power modules in the prior art.

FIG. 3 shows a schematic diagram of an intelligent power module according to the present invention.

### DESCRIPTION OF THE PREFERRED EMBODIMENTS

The drawings as referred to throughout the description of the present invention are for illustration only, to show the interrelations between the components or units, but not drawn according to actual scale of sizes.

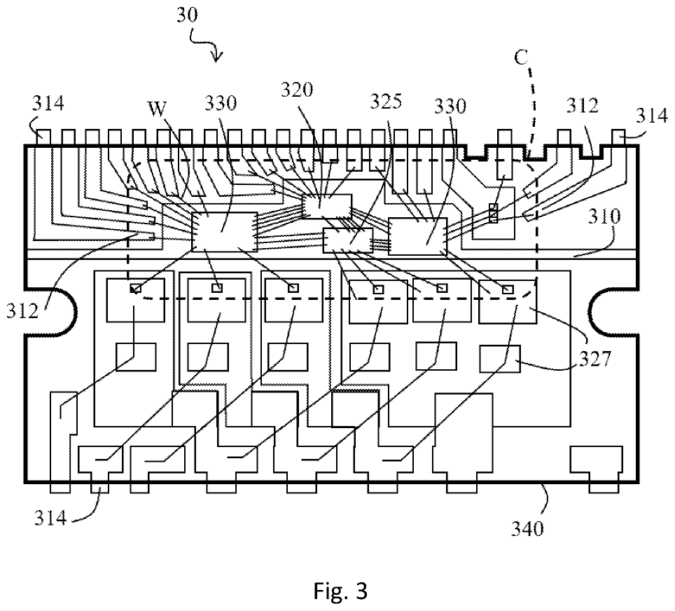

FIG. 3 shows an intelligent power module 30 of the present invention, which has advantages of small size, simple manufacturing process, concentrated layout of bonding wires W, and simple wiring layout. The intelligent power module 30 includes: a lead frame 310; plural signal processing chips 320, 325 and 327 disposed on the lead frame 310 (FIG. 3 shows three signal processing chips as an example; in other embodiments, the intelligent power module can include any other plural number of signal processing chips); at least one bridge die 330, configured to transmit signals among the signal processing chips 320, 325, 327; and an encapsulating structure 340, encapsulating the lead frame 310, the signal processing chips 320, 325 and 327, and the bridge die 330. Note that the layout of components shown in FIG. 3 is only for illustrative purpose, not for limiting the scope of the present invention. The layout can be arranged otherwise within the spirit of the present invention.

The aforementioned bridge die 330 may be produced by a semiconductor process, and it may include a single-layer or multi-layer circuit. The single-layer or multi-layer circuit can provide multiple signal connection lines between the signal processing chip 320, 325, and 327. That is, the bridge die 330 works as a bridge for connecting different signal connection lines, whereby the conventional PCB can be omitted and replaced by the bridge die 330, or at least can be simplified in the intelligent power module of the present invention, for higher space utilization efficiency and simplifying the layout of the wire bonding in the intelligent power module. The circuit in the bridge die 330 does not provide any calculation or signal processing function; it only provides signal connection/transmission function. In some embodiments of the present invention, the bridge die 330 completely replaces the PCB in the intelligent power module 330, so that there is none of PCB in the intelligent power module 330, to have a better space utilization efficiency and better wire bonding layout. FIG. 3 shows an example that there are two bridge dies 330 in the intelligent power module 330; this is only an example and the number of the bridge die(s) can be any natural number.

In this embodiment, the intelligent power module 30 does not need to accommodate the PCB, so it does not need a huge space for the PCB and the fixing bracket for fitting the PCB in the prior art. In this case, the signal processing chips do not have direct signal connection with any PCB, so the wiring layout becomes simpler, and the bonding wires W can be arranged in a neat way, whereby the package size of the intelligent power module 30 can be significantly reduced.

In one embodiment, the signal processing chips includes a main controller chip and at least one cooperating functional chip. For example, the main controller chip is an MCU, and the cooperating functional chips include a driver chip and a power chip. For another example, as shown in FIG. 3, the main controller chip is the MCU 320 and cooperating functional chips include the driver chip 325 and the power chip 327. The combination of the signal processing chips can be decided depending on the needs in application; the number and types of the signal processing chips are not limited to the embodiment shown in FIG. 3.

In one embodiment, the signal processing chips can be manufactured according to different semiconductor processes, such: insulated gate bipolar transistor (IGBT) manufacturing process, metal oxide semiconductor field effect transistor (MOSFET) manufacturing process, silicon carbide (SiC) transistor manufacturing process, etc. Any manufacturing process suitable for manufacturing the semiconductor chips of the present invention can be applied to the intelligent power module of the present invention.

As shown in FIG. 3, the bridge die 330 can be used to greatly simplify the layout of the bonding wires W among the chips; the number of the bonding wires W can be reduced as compared to the prior art because of the simplified layout. In one embodiment, the driver chip 325 of the present invention is a single-phase gate driver IC, but the present invention is not limited to this; in another embodiment, the driver chip 325 of the present invention includes a multi-phase gate driver IC, such as a three-phase gate driver IC, which for example can be manufactured by integrating multiple single-phase gate drivers together. Such integration can reduce the space required for the driver chip 325, and centralize and simplify the layout of the bonding wires W around the bridge die 330, to reduce the package size of the intelligent power module 30. Or alternatively, with the same package size as the prior art, the intelligent power module 30 of the present invention can integrate more functions. The single-layer or multi-layer circuits in the bridge die 330 can be connected to the signal processing chips 320, 325, 327 or the lead frame 310 via bonding fingers and bonding wires W for signal transmission.

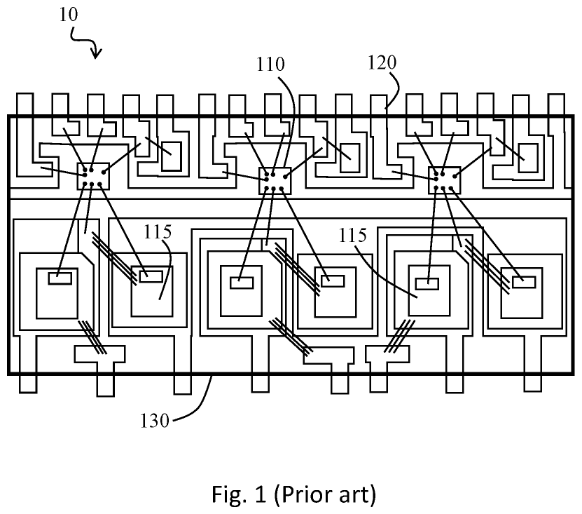

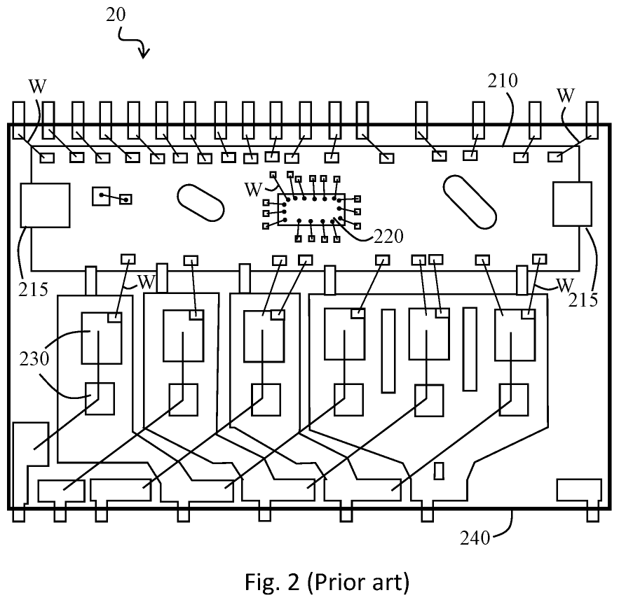

In one embodiment, by means of the bridge die 330, the number of the required driver chips 325 cooperating with the power chip 327 can be reduced, whereby the space utilization efficiency inside the intelligent power module 30 increases. For example, in FIG. 1 of the prior art, three driver chips 110 cooperate with six power chips 115. In the present invention, one driver chip 325 can cooperate with six power chips 327, wherein the space utilization efficiency increases significantly. The driver chip cooperating with the power chip 327 is not limited to that shown in FIG. 3; in other embodiments, the circuitry or the number of the driver chip(s) can be modified according to application purpose and requirements.

As shown in FIG. 3, in one embodiment, the bridge die 330 can transmit signals between a plurality of signal processing chips via a plurality of bonding wires W, wherein the layout of the bonding wires W is concentrated around the bridge die 330 (within the wiring concentration area C in the embodiment of FIG. 3). Compared with the messy layout of the bonding wires W in the prior art, the bridge die 330 in the present invention makes the layout of the bonding wires W to be more concentrated and much simpler.

In one embodiment, a portion of the lead frame 310 encapsulated by the encapsulating structure 340 includes a plurality of bonding fingers 312, each of which is connected to the signal processing chips 320, 325, 327 or the bridge die 330 by a corresponding bonding wire W. In one embodiment, besides the bonding wires W, the bridge die 330 can also be connected to the signal processing chip 320, 325, or 327, by through-silicon vias (TSVs), to further reduce the number of the bonding wires W. Besides the aforementioned bonding fingers 312, a portion of the lead frame 310 outside the encapsulating structure can include multiple leads 314. By the leads 314, the signal processing chip 320 transmits signals to and from the outside of the intelligent power module 30.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. For another example, a number, location, or design of the chips, the bonding fingers, the leads, or the bonding wires, can be modified according to embodying purpose. In view of the foregoing, the spirit of the present invention should cover all such and other modifications and variations, which should be interpreted to fall within the scope of the following claims and their equivalents.

What is claimed is:

1. An intelligent power module, including:
a lead frame;
a plurality of signal processing chips, disposed on the lead frame;
at least one bridge die, configured to operably transmit signals among the signal processing chips; and
an encapsulating structure, encapsulating the lead frame, the signal processing chips, and the at least one bridge die.

2. The intelligent power module according to claim 1, wherein the bridge die has a multi-layer circuit layout, which includes multiple signal connection lines configured to connect the signal processing chips.

3. The intelligent power module according to claim 1, wherein the signal processing chips do not have direct signal connection with a PCB.

4. The intelligent power module according to claim 1, wherein the signal processing chips include a combination of two or more of an MCU, a driver chip, and a power chip.

5. The intelligent power module according to claim 4, wherein the driver chip includes a three-phase gate driver IC.

6. The intelligent power module according to claim 1, wherein the bridge die transmits signals between the signal processing chips and the lead frame, via multiple bonding wires.

7. The intelligent power module according to claim 6, wherein a portion of the lead frame encapsulated by the encapsulating structure includes a plurality of bonding fingers, each of which is coupled to one of the signal processing chips or the bridge die via one of the bonding wires.

8. The intelligent power module according to claim 1, wherein the signal processing chips are manufactured by at least one of the following manufacturing processes: insulated gate bipolar transistor (IGBT) manufacturing process, metal oxide semiconductor field effect transistor (MOSFET) manufacturing process, and/or silicon carbide (SiC) transistor manufacturing process.

9. The intelligent power module according to claim 1, wherein a portion of the lead frame outside the encapsulating structure includes multiple leads, and the signal processing chips transmit signals to and from an outside of the intelligent power module via the leads.

10. The intelligent power module according to claim 1, wherein the bridge die includes a single-layer or multi-layer circuit manufactured by a semiconductor process, and includes at least one bonding pad, wherein the intelligent power module further includes bonding wires for transmitting signals among the bonding pad and the signal processing chips.
